(19) United States
(12) Patent Application Publication
(10) Pub. No.: US 2022/0418073 A1
(43) Pub. Date: Dec. 29, 2022

(54) INDUSTRIAL PLANT ENVIRONMENTAL CONDITION MAP USING LUMINAIRES

(71) Applicant: APPLETON GRP LLC, Rosemont, IL (US)

(72) Inventors: Timothy E. Graff, Arlington Heights, IL (US); Ravindra Viraj Gurjar, Pune (IN)

(21) Appl. No.: 17/374,562

(22) Filed: Jul. 13, 2021

(30) Foreign Application Priority Data
Jun. 29, 2021 (IN) 202121029045

(51) Int. Cl. H05B 47/19; G06F 30/13; G05B 23/02

(52) U.S. Cl. CPC H05B 47/19; G06F 30/13; G05B 23/027

(57) ABSTRACT

Luminaires which provide illumination (in some cases, in a coordinated manner with other nodes of a lighting network) in an industrial process plant include one or more environmental sensors to detect various environmental (e.g., ambient) conditions within the process plant. The luminaires transmit signals indicative of detected conditions (and optionally, respective measurements thereof) to a computing device or host which indicates, on a representation or map of a physical layout of the process plant, the respective detections at respective map locations corresponding to respective locations of the luminaires at the process plant to thereby generate an environmental condition map. The environmental condition map may be dynamically updated responsive to additional luminaire signals, utilized by a process control system to generate alarms, alerts, etc., and/or presented on user interfaces of the process control system and/or of the lighting network.

### CROSS-REFERENCE TO RELATED APPLICATIONS

This application claims priority to Indian Patent Application No. 202121029045, which was filed on Jun. 29, 2021 and entitled “Industrial Plant Environmental Condition Map Using Luminaires,” the entire contents of which are hereby incorporated by reference.

### FIELD OF THE DISCLOSURE

This disclosure relates to utilizing luminaires in industrial environments to provide or maintain communication network reliability during adverse conditions.

### BACKGROUND

The background description provided within this document is for the purpose of generally presenting the context of the disclosure. Work of the presently named inventors, to the extent described in this background section, as well as aspects of the description that may not otherwise qualify as prior art at the time of filing, are neither expressly nor impliedly admitted as prior art against the present disclosure.

Luminaires, lighting units, and light fixtures may provide general, ambient light, task or focused light, and/or emergency lighting within industrial environments such as industrial process plants, manufacturing facilities, oil refineries, power-generating systems, mines, warehouses, buildings, and the like. Some of these industrial environments may be hazardous environments and, accordingly, luminaires, lighting units, and light fixtures operating therein are required to be intrinsically safe and/or explosion proof, e.g., to prevent ignition and/or explosion of hazardous atmospheric mixtures such as flammable gases and/or dust, to protect electronics within the luminaire from being compromised or damaged, to contain any explosion that may occur, etc. Generally speaking, intrinsically safe and/or explosion proof luminaires, lighting units, and light fixtures are designed to limit undesirable and/or dangerous effects of thermal and/or electrical energy generated during both their normal use and maintenance, as well as during fault conditions.

Known luminaires, lighting units, and light fixtures in hazardous and/or in non-hazardous industrial environments may include or be attached to one or more sensors which sense, detect, and/or measure conditions in the environment in which the luminaires, lighting units, and light fixtures are located, such as ambient light, temperature, humidity, etc. More recently, “smart” luminaires, lighting units, and light fixtures have been designed to use computing functionality and lighting network connectivity to provide more sophisticated features, such as connected control of groups of luminaires of a lighting network, daylight harvesting (i.e., adjusting intensity by dimming or brightening based on the intensity of ambient light), and advanced motion detection (i.e., switching lights on and off based on the predicted motion of an individual through a facility). Further, within industrial environments, some smart luminaires, lighting units, and light fixtures may cooperate with process control systems to route process control messages on behalf of the process control system between various process control devices, components, and nodes, thereby leveraging the luminaires and the connected lighting network to deliver process control messages within an industrial environment.

### SUMMARY

Luminaires may be installed in various indoor and/or outdoor locations of an industrial environment to provide ambient, directed, task, and/or emergency lighting. The luminaires may be powered primarily via mains power, such as alternating-current (AC) electric power delivered to the industrial environment via an electrical power grid infrastructure or other outside electrical power source. Wiring which delivers power to the various luminaires is typically enclosed and shielded from the harsh industrial environment, e.g., behind a wall or ceiling, within conduit or other physical shields, etc. Each luminaire may include a battery or other local power storage device, which the luminaire may utilize in the event of mains power loss. Luminaires may be stand-alone luminaires, or may be communicatively connected via a connected lighting network to perform and coordinate the execution of smart lighting features within the industrial environment. For example, the luminaires may communicate with other luminaires and other nodes (such as back-end servers, data historians, user interface devices, etc.) via a lighting network to coordinate illumination functions within the environment, transmit status and/or other administrative messages related to lighting activities, etc. The lighting network may include wireless and/or wired portions, for example. In some embodiments, a luminaire may include one or more environmental sensors which detect and measure environmental or ambient conditions in the area in which the luminaire is disposed. For example, a luminaire may include an ambient temperature sensor, an ambient light sensor (e.g., visible light), a humidity sensor, a heat sensor, a motion sensor, one or more gas sensors (e.g., for various gases), a sound or noise sensor, a vibration sensor, an air flow sensor, etc. Luminaires which are outfitted with sensors may transmit sensor data to a back-end server of the lighting network, for example.

Many industrial environments serviced by the luminaires utilize one or more wired and wireless process control networks (also referred to interchangeably herein as “process control communication networks,” “process control data networks,” “industrial networks,” “industrial communication networks,” or “industrial data networks”) to send and receive process control messages (e.g., data, commands, statuses, and the like) to and from various components, devices, and/or nodes to thereby control an industrial process. For example, a process control system (PCS) within an industrial environment may utilize the one or more process control wireless networks, which may be mesh wireless networks, to transmit and receive process control and other related messages. Components, devices, and/or nodes within the industrial environment may transmit messages via the one or more wireless networks, typically by utilizing a standardized protocol that is particularly designed for industrial control applications. That is, the industrial wireless protocol utilized by an industrial wireless communication network enables the timing and delivery of process control messages to and from receiving and sending nodes in industrial environments so that nodes may operate on the message contents within specified time intervals to control respective portions of the process. Specifically, the delivery of process control messages via the wireless network is scheduled and controlled across the network so that the industrial process does not become unstable and the wireless network does not become overloaded and thereby cause errors, faults, uncontrolled behaviors, and in some cases, dangerous consequences such as explosions, leaks, fires, and the like, which may lead to loss of equipment and more importantly, loss of human life. An example of such a commonly utilized wireless industrial protocol is WirelessHART; however, any suitable wireless protocol which supports the scheduling and time-synchronization of the delivery and reception of process control messages between nodes of the network to control an industrial process and thereby manage risk within the industrial environment may be utilized. Generally speaking, a wireless network manager generates or creates a network schedule for the industrial wireless communication network, and the network manager provides respective portions of the schedule to nodes of the wireless network so that each node is configured to access the wireless network at respective scheduled or designated times or time slots to send and/or receive process control related messages, and so that communications between nodes of the industrial wireless communications network are delivered in a coordinated and controlled manner across the network.

In some industrial process plants, at least a part of the wireless portion of the lighting network and the wireless portion of process control network intersect or are integral. Both lighting communications and process control communications may be delivered via the intersecting/integral wireless portions, and the network manager may manage the scheduling for both the lighting communications and the process control communications via the intersecting/integral wireless portions.

Within an industrial environment such as an industrial process plant, lighting networks and process control networks may cooperatively operate to map and continuously update environmental conditions within the industrial process plant. In an embodiment, a computing device may obtain a representation of a physical layout of at least a portion of the industrial process plant, e.g., from the process control system or an asset management system of the plant. Additionally, the computing device may obtain signals indicative of environmental conditions detected or sensed by various sensors disposed at various luminaires within the lighting network servicing the process plant. Based on the physical layout of the plant, the physical locations at which the luminaires are disposed in and around the plant, and the sensed environmental conditions, the computing device may generate a map including indications of one or more detected environmental conditions at respective map locations corresponding to the respective physical locations of the luminaires which detected the environmental conditions. The map may be presented at a user interface associated with the lighting network and/or associated with the process control network. Further, the map (and its presentation on the user interface) may be continually updated over time as updated sensor information is received at the computing device from the luminaires. In some embodiments, the computing device or process control system may monitor the (continually updated) environmental condition map for various threshold, alert, and/or alarm conditions indicated by the sensed environmental data, and may alert operators to undesirable or dangerous conditions and their respective locations as the conditions are unfolding and changing as sensed by the detectors of the luminaires so that the operators may take mitigating actions. In some embodiments, the process control system itself may take mitigating actions based on observed and/or predicted environmental conditions at their detected locations, e.g., as indicated by the luminaires of the lighting network.

### BRIEF DESCRIPTION OF THE DRAWINGS

FIG. 1 illustrates an example industrial environment in which environmental condition maps may be generated and updated maintained by utilizing the systems, methods, luminaires, and/or techniques of the present disclosure.

FIG. 2 is a block diagram of an example luminaire which may be used in the exemplary industrial environment of FIG. 1.

FIG. 3 is a block diagram of an example computing device particularly configured to generate an environmental condition map of an industrial environment in accordance with at least a portion of the methods and/or systems disclosed herein.

FIG. 4 is a flow diagram of an exemplary method of generating a map of environmental conditions of an industrial process plant.

FIGS. 5A-5D illustrate various embodiments of environmental conditions maps, which may be generated by the methods, systems, and techniques disclosed herein.

### DETAILED DESCRIPTION

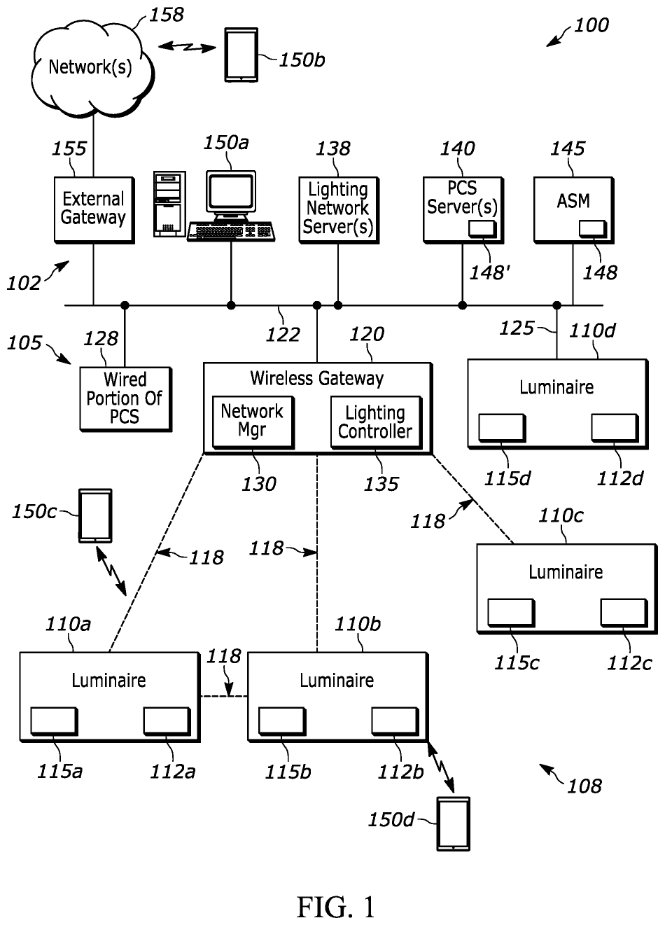

FIG. 1 illustrates an example industrial environment 100 in which embodiments of the systems, methods, luminaires, and techniques described herein may be implemented. In some situations, the example industrial environment may be disposed within a hazardous environment 100, such as an industrial process plant, a manufacturing facility, an oil refinery, a power-generating system, a mine, etc. in which components (such as luminaires, communication networks, process control devices, etc.) As interchangeably utilized herein, the terms “luminaire,” lighting unit“, and “light fixture generally refer to an electrically powered component which operate to supply general or ambient light and/or task or focused light in the portion of the electromagnetic spectrum that is visible to the human eye, e.g., from about 380 to 740 nanometers. As shown in FIG. 1, the industrial environment 100 includes a back-end environment 102 and a field environment 105. In some industrial environments 100, such as those of an industrial process plant, a manufacturing facility, an oil refinery, a power-generating system, a mine, etc., the field environment 105 is a hazardous environment. Accordingly components disposed within the hazardous field environment 105 (e.g., luminaires, communication network components, process control devices, etc.) must comply with all standards and/or regulatory rules that are applicable to the particular hazardous environment in which they are disposed to limit undesirable and/or dangerous effects of thermal and/or electrical energy generated during both their normal use and maintenance, as well as during fault conditions.

As shown in FIG. 1, the industrial environment 100 is serviced by a lighting network 108 which may provide general lighting, ambient light, task or focused lighting, and/or emergency lighting within the industrial environment 100. The lighting network 108 includes four luminaires 110a, 110b, 110c, 110d which are configured according to one or more of the techniques described herein and which are disposed at various physical locations within the field environment 105. For example, each of the luminaires 110a, 110b, 110c, 110d is respectively configured 112a, 112b, 112c, 112d (e.g., via hardware and/or via computer-executable instructions and configurations stored on memories and executed by processors) to provide illumination, to detect or sense and report one or more environmental or ambient conditions, as well as to perform other actions and techniques related thereto as described herein. To this end, each luminaire 110a-110d includes one or more respective environmental sensors 115a-115d which detect the environmental or ambient conditions. For example, environmental sensors 115a-115d may include ambient temperature, heat, ambient light, humidity, motion, particular gas, sound or noise, vibration, air flow, and/or other types of sensors or detectors. Each luminaire 110a-110d need not include a same or even similar types of sensors. For example, luminaires 110a, 110b may each include a gas sensor for a specific type of gas, and luminaires 110c, 110d may each omit any gas sensor, while luminaires 110a, 110c may each include an ambient temperature sensor and luminaires 110b, 110d may each omit any ambient temperature sensors. Further, some luminaires of the lighting network 108 may not include any environmental sensors (not shown).

In FIG. 1, each of the luminaires 110a, 110b, 110c is a respective node of a wireless portion 118 of the lighting network 108 (wireless links of which are denoted in FIG. 1 by the dashed lines). In an embodiment, the wireless portion 118 of the lighting network 108 (which is interchangeably referred to herein as the “wireless lighting network 118”) may be a wireless mesh network which utilizes a time-synchronized wireless protocol. The wireless lighting network 118 may include a wireless gateway 120 which communicatively connects, e.g., via a data highway or backbone 122, the wireless luminaires 110a, 110b, 110c to a wired portion 125 of the lighting network 108, which includes one or more wired luminaires 110d, and/or to lighting network components disposed in the back-end environment 102. The data highway or backbone 122 may be an Ethernet, broadband fiber optic, or any suitable type or types of wired backbone(s), for example.

In some configurations of industrial environment 100, at least part of the wireless portion 118 of the lighting network 108 may include, intersect, or be integral with a wireless process control network to which process control wireless nodes (not shown in FIG. 1) are communicatively connected, where the process control wireless nodes are included in a process control system (PCS) servicing the industrial environment 100, and where the process control wireless nodes are operable, via the PCS, to control an industrial process within the industrial environment 100. Examples of process control wireless nodes may include wireless field devices, wireless adaptors servicing respective wired field devices, routers, and/or other types of process control devices. A wireless gateway 120 servicing the wireless process control network may communicatively connect wireless process control devices and a wired portion 128 of the process control system, e.g., via the data highway or backbone 122 utilized by the lighting network, or via another data highway or backbone (not shown). The wired portion 128 of the PCS may be disposed at least in part in the field environment 105 of the industrial environment 100, and may include, for example, controllers, I/O devices, marshalling equipment, wired field devices, and/or other types of wired process control devices.

In the embodiment shown in FIG. 1, the depicted wireless network 118 services both wireless luminaires 110a, 110b, 110c of the lighting network 108 and wireless process control devices (not shown) of the process control system (PCS). Accordingly, FIG. 1 depicts the wireless gateway of the lighting network and the wireless gateway of the PCS as being an integral wireless gateway 120, and both the lighting network 108 and the process control network share a common data highway 122. In other embodiments, though, the wireless gateway of the PCS and the wireless gateway of the lighting network may be different or separate wireless gateways 120, and/or the lighting network 108 and the process control network may utilize different data highways 122 via which to respectively connect respective field environment components 105 and respective back-end environment components 102.

As mentioned above, the wireless portion 118 of the lighting network 108 may utilize a time-synchronized wireless protocol such as WirelessHART or other suitable wireless protocol to deliver control, data, and other types of messages to, from, and between wireless luminaires 110a-110c. Accordingly, the wireless portion 118 of the lighting network 108 includes a wireless network manager 130 which, as denoted in FIG. 1, is included in the wireless gateway 120. (In other embodiments, though, the wireless network manager 130 may be a separate node of the wireless lighting network 118 and may not be integral with the wireless gateway 120.) As previously discussed, the wireless network manager 130 performs administrative and coordination tasks related to the wireless lighting network 118, such as generating, re-organizing, updating, and administrating a network schedule, distributing respective portions of the network schedule to respective luminaires 110a-110c, managing time-synchronization among wireless luminaires 110a-110c, delivering messages between the wireless portion 118 of the lighting network 108 and the back-end environment 102 and/or the wired portion 125 of the lighting network 108, for example. In configurations in which the wireless portion 118 of the lighting network 108 and the wireless process control network are at least in part an integral wireless network, e.g., as depicted in FIG. 1, both the wireless portion of the lighting network 108 and the wireless process control network may be under the direction of the same network manager 130, e.g., for scheduling, time synchronization, and other such purposes.

Generally speaking, the wireless luminaire nodes 110a, 110b, 110c and the wired luminaire node(s) 110d of the lighting network 108 operate to coordinate and control illumination within the industrial environment 100, as well as to perform other tasks related to providing illumination, e.g., by sending and receiving lighting control, data, and other types of messages via the lighting network 108. In embodiments, the lighting network 108 includes a lighting controller 135 which coordinates lighting/illumination activities of the lighting network 108 and administration thereof. In FIG. 1, the lighting controller 135 is illustrated as being included in the wireless gateway 120; however, the lighting controller 135 may be included in any desired node of the lighting network 108, for example, in a back-end lighting network server 138, in a stand-alone wired or wireless node of the lighting network 108, etc. Typically, though, the lighting controller 135 typically is communicatively connected to the data highway 122. The lighting controller 135 may be in communicative connection with the network manager 130, and in some embodiments, the lighting controller 135 and the network manager 130 are an integral unit (not shown).

The back-end environment 102 of the industrial environment 100 is protected from the harsh conditions of the field environment 105, and as such, various components of back-end may be safely disposed in the back-environment 102. For example, one or more back-end servers 138 of the lighting network 108 may be disposed in the back-end environment 102, and may provide functionalities to support the coordinated illumination provided by the lighting network 108, such as configuration, control instructions, data historian, analytics, reporting, etc. Additionally, one or more back-end servers 140 of the process control system (PCS) may be disposed in the back-end environment 102, and may provide functionalities which support the real-time operations of the PCS such as configuration, virtual control, data historian, analytics, reporting, etc. It is noted that although the lighting network back-end servers 138 and the PCS back-end servers 140 are illustrated in FIG. 1 as being independent sets of servers, in some embodiments (not shown), at least a portion of the lighting network back-end servers 138 and at least a portion of the PCS servers 140 may be implemented as one or more integral servers. Further, in embodiments, at least a part of the lighting network servers 138 and/or at least a part of the PCS back-end servers 140 may be physically disposed in locations which are physically remote from the environment 100, such as at remote server banks, in a cloud computing system, etc. As shown in FIG. 1, both the PCS back-end servers 140 and the lighting network back-end servers 138 may be communicatively connected to the data highway 122.

Additionally, the back-end 102 of the industrial environment 100 may include an Asset Management System (ASM) 145 of the process plant. As shown in FIG. 1, the ASM 145 may be communicatively connected to the data highway 122, however, the communicative connection between the ASM 145 and the data highway 122 is not required. Generally speaking, while the PCS servers 140 are primarily (but not exclusively) directed to run-time operations of the process plant, the ASM 145 is primarily (but not exclusively) directed to managing the risk of failure of assets of the process plant, where assets include physical equipment and optionally software assets. For example, lifetimes and scheduled or routine maintenance, replacement, and upgrades of various assets may be tracked and managed via the ASM 145. As shown in FIG. 1, the ASM 145 stores an indication of a physical layout 148 of the process plant which depicts or otherwise identifies physical locations of assets, devices, equipment, piping, aisles, walkways (raised or floor level), rooms, walls, floors, ceilings, doors, and other physical contents and characteristics of the plant. The physical layout 148 may be a three-dimensional physical layout, and as such may identify the physical locations of the contents and characteristics of the plant via three-dimensional coordinates, such as GPS (Global Positioning System) coordinates or other suitable coordinates. The layout 148 may be generated based on one or more maps, drawings, diagrams, blueprints, or other types of plans of the process plant, such as P&ID (Piping and Instrumentation Diagrams), construction blueprints, etc., for example. In some arrangements of the industrial environment 100, a copy of at least a portion of the physical layout 148 of the plant may be stored in the PCS servers 140, as denoted in FIG. 1 by the reference 148′. For example, a copy 148′ of at least a portion of the physical layout 148 may be transmitted by the ASM 145 to the PCS servers 140 via the data highway 122, the copy 148′ may be manually transferred from the ASM 145 to the PCS servers 140, or the ASM 148 may store the copy 148′ in a data storage device (not shown in FIG. 1) which is accessible to both the ASM 145 and the PCS servers 140, and the PCS servers 140 may retrieve the stored copy 148′ from the data storage device.

The back-end environment 102 of the industrial environment 100 may also include one or more locally or remotely disposed user interface devices 150a-150b, which may include locally or remotely disposed computing devices, such as desktops, laptops, tablets, phones, smart devices, connected vehicle devices, and/or other types of Personal Electronic Devices (PEDs). For example, one or more user interface devices 150a utilized respectively by operators and/or by configuration engineers of the process control system and/or of the lighting network 108 may be locally connected in a wired manner to the data highway 122. One or more user interface devices 150b utilized respectively by operators and/or by configuration engineers of the process control system and/or of the lighting network 108 may be disposed remotely from the industrial environment site 100, and may be communicatively connected to the data highway 122 via a system or external gateway 155 and one or more public and/or private communications or data networks 158, for example. Additionally or alternatively, one or more user interface devices 150c, 150d may be utilized by personnel located within the field environment 105 of the industrial environment 100, where the devices 150c, 150d may be communicatively connected to the wireless lighting network 118 or via direct local means. For example, the user interface devices 150c may be communicatively connected to the wireless lighting network 118 and/or the wireless process control networks (or nodes thereof) via networking means, e.g., by utilizing a generic last-mile wireless local network (e.g., Wi-Fi, cellular, short-range wireless protocols, etc.) proximate to or included in the field environment 105, the one or more public and/or private networks 158, and the system gateway 155. In another example, the user interface device 150d may be communicatively connected to a wireless luminaire 110b via a short-range wireless protocol (e.g., Bluetooth, NFC, etc.), and the wireless luminaire 110b may deliver communications to/from the user interface device 150b and the wireless lighting network 118 and/or the wireless process control network.

Further, as shown in FIG. 1, each user interface device 150a-150d may execute applications, thin clients, or other types of user interfaces, each of which services the process control system, the lighting system 108, or both systems. For example, the user interface device 150a which is physically disposed in the back-end environment 102 of the industrial environment 100 may include (and execute) one or more process control system-specific user interface applications and/or one or more lighting system-specific user interface applications. In another example, a remote user interface device 150b (e.g., which is utilized by remotely located personnel) may execute one or more applications, thin clients, etc. corresponding to one or more process control system user interfaces, one or more lighting system interfaces, or both. In still another example, user interface device 150c may be configured to only service the process control system and not the lighting system, and thus executes process control user interfaces (e.g., which may communicate with the process control system via wireless network 118) and not lighting system user interfaces. User interface device 150d may be configured to service only the lighting system and not the process control system, and thus executes lighting system user interfaces (e.g., which may communicate with the lighting system via the lighting network 108) and not process control system user interfaces.

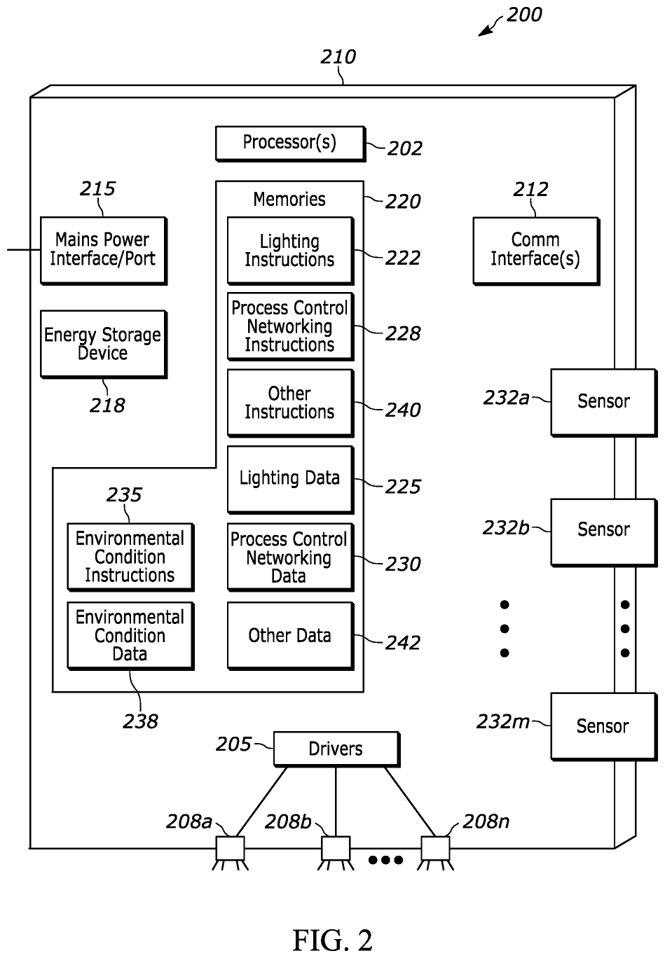

FIG. 2 is a block diagram of an example luminaire node 200 which may be used in the exemplary industrial environment of FIG. 1. For example, one or more portions or the entirety of the luminaire node 200 may be included in the luminaire node 110a, 110b, and/or 110c of FIG. 1, or may be included in other luminaires which are communicatively connected via the lighting network 108. The luminaire node 200 is described with simultaneous reference to FIG. 1; however, this is merely for clarity of illustration and not limitation purposes. For example, instances of the luminaire node 200 may be utilized in environments other than the industrial environment 100.

The luminaire node 200 includes one or more processors 202, one or more drivers 205 (e.g., for illumination or visible light sources), and one or more illumination or visible light sources 208a-208n that are enclosed in, surrounded by, and/or otherwise protected by an enclosure 210, which may be a hazardous environment enclosure. Additionally, the luminaire node 200 includes one or more communication interfaces 212 via which the luminaire node 200 may communicatively connect to a wireless lighting network and optionally to a wireless process control network, and thus the one or more communication interfaces 212 may include respective digital signal processors (DSPs), transceivers, antennas, etc. For example, the one or more communication interfaces 212 may include one or more wireless communication interfaces via which the luminaire node 200 wirelessly communicates with the wireless network 118 (e.g., via WirelessHART or other suitable time-synchronized wireless protocol) and optionally with the lighting network (e.g., via the time-synchronized wireless protocol or some other suitable wireless protocol). In some embodiments, the one or more communication interfaces 212 may include one or more wired interfaces via which the luminaire node 200 communicates in a wired manner with other luminaires and components of the lighting network 108. In some embodiments, the one or more communication interfaces 212 may include a hybrid wired/wireless communication interface.

The luminaire node 200 includes a mains power interface or port 215 electrically connecting the luminaire node 200 to a source of mains power, which typically is a general-purpose alternating-current (AC) electric supply, such as provided by utility power, an electric grid, a generator, etc. For the most part, during normal operations, the luminaire node 200 may be powered via the mains power received via the mains power interface/port 215. The luminaire node 200 also includes an energy storage device 218 such as a battery, capacitor, or other suitable power storage device which may serve as a back-up source of power, and via which the luminaire node 200 may be powered during certain situations, such as when mains power is disconnected, intermittent, or otherwise not available. Typically, upon detecting that mains power is no longer available via the mains power interface 215, the luminaire node 200 may automatically switch to using the energy storage device 218 as its source of power, and upon detecting that mains power is restored, the luminaire node 200 may automatically return to utilizing mains power as its primary source of energy.

Generally speaking, for the purposes of providing illumination or visible lighting as well as to perform tasks related to illumination/lighting (such as administrative tasks, diagnostics, maintenance operations, etc.), the luminaire node 200 includes one or more memories 220 storing a set of computer-executable lighting instructions 222. The one or more processors 202 may execute the lighting instructions 222 to cause the luminaire node 200 to perform lighting-related tasks, such as instructing the one or more drivers 205 to energize or activate the one or more illumination sources 208a-208n, e.g., individually or independently, and/or as a set or group in a coordinated manner. For example, the executing lighting instructions 222 may instruct the one or more drivers 205 to energize, activate, de-energize, or deactivate the one or more illumination sources 208a-208n of the luminaire node 200 based on sensor signals or other detected conditions. If the luminaire node 200 is connected to the lighting network 108 (e.g., in a wireless or wired manner), the executing lighting instructions 222 may instruct the one or more drivers 205 to energize, activate, de-energize, or deactivate the one or more illumination sources 208a-208n of the luminaire node 200 based on driving commands which are transmitted by the lighting controller 135 of the lighting network 108 (not shown in FIG. 2) and received at the luminaire node 200 via the communication interfaces 212 and lighting network 108. In some connected lighting configurations, the one or more processors 202 may execute the lighting instructions 222 to send administrative messages to (and/or receive administrative messages from) the lighting controller 135 via the communication interfaces 212 and the lighting network 108, such as usage statistics, component status, and the like, to perform diagnostics, etc. Lighting data 225 which the luminaire node 200 utilizes (and in some cases, reads and/or writes) to perform lighting-related functions, activities, and tasks may be stored in the one or more memories 220 of the luminaire node 200. The lighting data 225 may store, for example, the portion of the network schedule (e.g., as generated by and received from the wireless network manager 130) which defines or directs the luminaire node's lighting-related communications, a configuration of the luminaire node 200 as a lighting node within the lighting network 108 or as a stand-alone luminaire 200, records of lighting events, data, diagnostic results, and/or statistics, and the like.

When the luminaire node 200 serves as a node of the wireless process control system 118, the luminaire node 200 may further include a set of process control networking instructions 228 stored on its one or more memories 220. The one or more processors 202 may execute the process control networking instructions 228 to cause the luminaire node 200 to perform process control networking tasks, such as routing process control messages to and from other process control wireless nodes in accordance with the time-synchronized schedule generated by the network manager 130 of the wireless network 118. For example, when the luminaire node 110a is configured as an instance of the luminaire node 200, the luminaire node may receive, from the PCS servers 140 of the back-end environment 102, process control messages to be routed to other wireless process control devices and may forward (via process control wireless network 118) such messages to/from their respective recipients (e.g., wireless field devices, not shown) in accordance with the network schedule. In a similar manner, when the luminaire node 110c is configured as an instance of the luminaire node 200, the luminaire node 110c may receive process control messages from a wired or wireless process control field device (not shown), and may forward (e.g., via wireless network 118) such messages to their respective recipients in accordance with the network schedule. As such, the memories 220 of the luminaire node 220 store process control networking data 230 to support process control networking tasks performed by the luminaire node 200. For example, the process control networking data 230 may store the portion of the network schedule (e.g., as generated by and received from the wireless network manager 130) which defines or directs the luminaire node's process control message routing activities, a configuration of the luminaire node 200 as a wireless node within the wireless network 118, records of process control networking events, data, and/or statistics, and the like.

As shown in FIG. 2, the luminaire node 200 includes one or more environmental sensors 232a-232m which are communicatively connected to other components of the luminaire 200, e.g., the processor(s), the memories 220, etc. For example, the sensors 232a-232m may be the sensors 110a, 110b, 110c, or 110d of FIG. 1. The one or more environmental sensors 232a-232m may detect, sense, and/or measure one or more environmental conditions (e.g., ambient conditions or conditions of the immediate environment in which the luminaire 200 is physically located), such as ambient temperature, heat, ambient light, humidity, motion, particular gas, sound or noise, vibration, air flow, etc. A single sensor 232x may detect a single environmental condition, or may detect multiple environmental conditions, and each sensor 232x may generate signals, e.g., over time, indicative of the detected condition(s) and optionally indicative of measurement(s) of the detected condition(s). Advantageously, the sensors 232a-232m may be conveniently powered by the mains power 215 and/or the battery power 218 provided to the luminaire 200.

The luminaire 200 also includes a set of environmental condition instructions 235 stored on its one or more memories 220. The one or more processors 202 may execute the environmental condition instructions 235 to cause the luminaire node 200 to obtain, from the signals generated by the one or more environmental sensors 232, data indicative of conditions that have been detected, sensed, and/or measured by the one or more environmental sensors 232 (e.g., environmental condition data 238), and to associate respective timestamps or other suitable indications of respective times at which the environmental condition data 238 was collected or observed. The environmental condition data 238 and corresponding timestamps may be stored in the luminaire memories 222, and/or may be transmitted to the lighting network server(s) 138, e.g., via the communication interface(s) 212 and the lighting network 108. For example, the processor(s) 202 may execute the environmental condition instructions 235 to cause the environmental condition data 238 to be transmitted to the lighting network server(s) 138 in accordance with the time-synchronized schedule generated by the network manager 130.

Of course, the memories 220 of the luminaire node 200 may store other instructions 240 and other data 242 in addition to those related to lighting, process control, and environmental conditions.

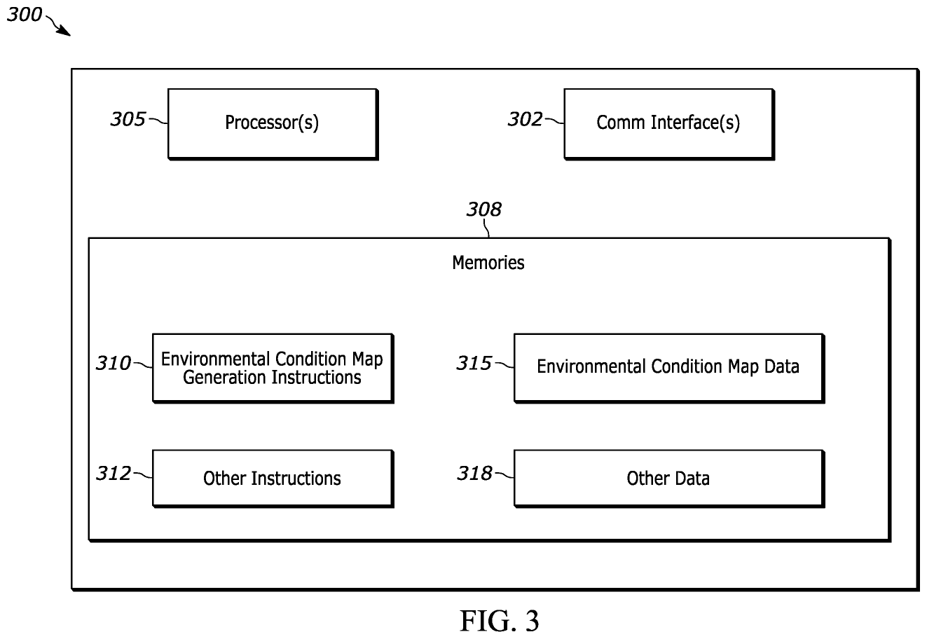

FIG. 3 is a block diagram of an example computing device 300 which is particularly configured to generate a map of environmental conditions (e.g., an environmental condition map) of an industrial environment in accordance with at least a portion of the methods and/or systems disclosed herein. For example, and referring to FIG. 1, the computing device 300 may be included in the one or more lighting network servers 138, in the one or more PCS servers 140, in the wireless gateway 102, or in another set of computing devices which are communicatively connected to the data highway 122 of the industrial environment 100, either locally via a direct connection to the data highway 122, or remotely via the external gateway 155 and one or more external networks 158. For example, the computing device 300 may be included in an Industrial Internet of Things (IIOT) server. For ease of discussion, and not for limitation purposes, the computing device 300 is discussed herein with simultaneous reference to the industrial environment 100 of FIG. 1, although the computing device 300 may be additionally or alternatively utilized in other industrial environments. For example, a single instance of the computing device 300 may generate environmental condition maps for multiple different industrial environments. Further, although FIG. 3 depicts the computing device 300 as a single computing device, in some embodiments the components of the computing device 300 may be implemented in a group of computing devices, such as a bank of servers, a cloud computing system, one or more networked computing devices, etc. For ease of discussion, though, the computing device 300 is discussed herein using the singular tense.

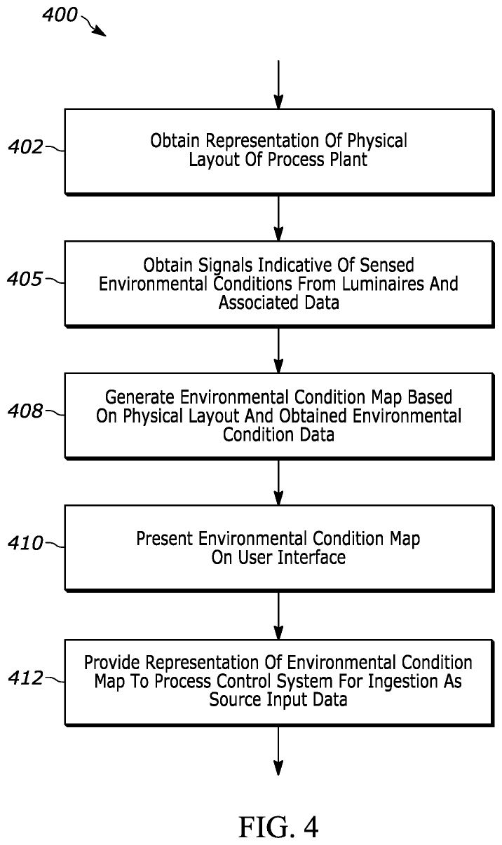

The computing device 300 includes one or more network or communication interfaces 302 via which the computing device 300 may communicatively connect to the data highway 122, the lighting network servers 138, the PCS servers 140, and the ASM 145. Additionally, the computing device 300 includes one or more processors 305 and one or more tangible, non-transitory memories 308 on which environmental condition map generation instructions 310 and optionally other instructions 312 are stored. The sets of instructions 310, 312 may be implemented as programs, applications, instructions, services, modules, routines, and the like, which may be executed by the one or more processors 305 to perform various tasks associated with generating and updating an environmental condition map, for example. For example, the environmental map generating instructions 310 may be executable by the one or more processors 305 to perform at least a portion of embodiments of the method 400 of FIG. 4, and/or to perform at least portions of other methods of generating and updating an environmental condition map for an industrial process plant. Additionally, the one or more memories 308 of the computing device 300 may store environmental condition map data 315 and optionally other related data 318 utilized in conjunction with generating and updating an environmental condition map. For example, collected sensor data, at least portions of the layout map 148 provided by the ASM 145, current environmental maps, and previous environmental map snapshots may be stored as environmental map data 315.

Turning to FIG. 4, FIG. 4 depicts a flow diagram of an example method 400 for generating a map of environmental conditions (e.g., an environmental condition map) of an industrial environment, such an industrial process plant. For example, the lighting network servers 138 of FIG. 1, the PCS servers 140 of FIG. 1, the wireless gateway 120, or the computing device 300 of FIG. 3 may perform at least a portion of the method 400. In an example implementation, the computing device 300 performs at least a portion of the method 400, e.g., by executing the instructions 310. For ease of discussion, and not for limitation purposes, though, this disclosure discusses the method 400 with simultaneous reference to the industrial environment 100 of FIG. 1, the luminaire 200 of FIG. 2, and/or the computing device 300 of FIG. 3, although the method 400 may execute in environments other than the environment 100, in conjunction with luminaire nodes other than the luminaire nodes 200, and by computing devices other than computing device 300. Additionally, in some embodiments, the method 400 includes one or more alternate and/or additional actions other than those shown in FIG. 4.

At a block 402, the method 400 includes obtaining a representation of a physical layout of at least a portion of an industrial process plant, e.g., from a process control system or from an asset management system of the industrial process plant. The physical layout may include indications of respective locations (e.g., three-dimensional locations) of a plurality of devices, pieces of equipment, piping, components, walls, ceilings, doors, and other physical assets which are physically disposed in the industrial process plant. For example, the computing device 300 may obtain a copy of at least a portion of the physical layout 148 stored at an ASM 145 of the industrial process plant, e.g., from the ASM 145. In some embodiments, the computing device 300 may obtain a copy of at least a portion of the physical layout 148 from the PCS servers 140 or from a data storage device (not shown in FIG. 1) which is accessible to both the ASM 145 and the computing device 300 and into which the ASM 145 has stored a copy of the physical layout 148.

At a block 405, the method 400 includes obtaining, from one or more luminaires of a lighting network providing illumination at the industrial process plant, respective signals indicative of one or more environmental conditions of the industrial process plant which are detectable or able to be sensed by respective sensors disposed at each luminaire. For example, the one or more luminaires may be instances of the luminaire 200, for of some other type of luminaire. The respective signals may be indicative of the detection, lack or absence of detection, sensing, magnitude, and/or measurement of various environmental conditions such as ambient temperature, humidity, ambient visible light, motion, air flow, a particular gas, sound or noise, vibration, or some other type of environmental condition. The obtained signals may include a corresponding time stamp or other suitable indication of a respective time/date of observation of the sensed or detected (or undetected, as the case may be) environmental condition. Further, as each luminaire may include different sets of sensors, each luminaire may detect or sense only the environmental conditions which are detectable by its respective sensors.

Significantly, as the environmental conditions are sensed by sensors associated with luminaires having known physical locations (e.g., known three-dimensional physical locations) in and around the process plant, a sensed environmental condition is not only associated with a time/date at which the condition was sensed, but also is associated with a specific three-dimensional location at which the condition was sensed. A luminaire may provide its physical location in conjunction with the signal indicative of the environmental condition, or the lighting network servers 138 may determine the physical location of the luminaire (and therefore, of the sensed environmental condition) based on the identity of the luminaire which generated the signal. Accordingly, the sensed environmental condition (e.g., its presence, absence, magnitude, measurement, etc.), the time/date at which the environmental condition was sensed or detected, and the physical location of the luminaire which includes one or more sensors via which the environmental condition may be detected are collectively and generally referred to herein as “environmental data” or “sensed environmental data.” As such, the block 405 may include obtaining environmental data from and corresponding to one or more luminaires servicing the industrial process plant.

Industrial process plants may include multiple luminaires disposed at multiple physical locations in and around the plant, where the luminaires may be communicatively connected by a lighting network via which lighting control messages are delivered to thereby control the illumination provided by the plurality of luminaires at the industrial process plant. In these industrial plants, obtaining 405 the respective signals indicative of the detected or sensed environmental condition(s) (or lack thereof, as the case may be) and associated environmental data (e.g., time, location, etc.) may include obtaining at least some of the respective signals/environmental data via the lighting controller 135, the wireless gateway 120, the wireless lighting network 118, and/or the wired lighting network 125, e.g., as the signals/data are generated and transmitted by various luminaires 110a-110d. Additionally or alternatively, the block 405 may include obtaining at least some of the respective environmental condition signals (and associated environmental data) from the lighting network servers 138. For example, the lighting network servers 138 may collect the signals indicative of the environmental conditions from the luminaires 110a-110d and corresponding time and location data, and may optionally store indications of the collected signals/environmental data. Subsequently the lighting network servers 138 may forward to the computing device 300 (and/or allow the computing device 300 to access or otherwise obtain) at least a portion of the stored signal/environmental data information. For instance, the computing device 300 may obtain a subset of the stored signal/environmental data information based on one or more criteria, e.g., an area of the plant, a time interval, only updated information, type of environmental condition, etc.

At a block 408, the method 400 includes generating a map including indications of information indicative or descriptive of the environmental condition or conditions at respective map locations corresponding to respective physical locations of the plurality of luminaires at the industrial process plant, thereby generating a map of the environmental condition or conditions for the industrial process plant. For example, the computing device 300 may overlay a representation of the physical layout of at least the portion of the industrial process plant with the indications of the information corresponding to the environmental condition or conditions (e.g., indications of the presence and/or respective magnitudes or measurements of environmental conditions) to thereby generate the environmental condition map.

In embodiments (not shown), the method 400 may include determining or calculating information indicative of the environmental condition or conditions based on the signals obtained from the luminaires and further based on additional environmental information. For example, the signals obtained from the luminaires (block 405) may include ambient temperature measurements, and the method 400 may include determining isothermal ranges of various areas of the process plant based on the obtained ambient temperature measurements as well as other information such as facility structures, wind direction, wind speed, solar influences, and the like. The additional environmental information may be obtained from databases (e.g., fixed environmental information such as facility structure locations and materials), from signals generated by other types of sensors disposed at one or more of the luminaires, and/or from signals generated other sensor systems within the industrial plant.

Further, the environmental condition map may be generated 408 in any format suitable for a consumer of the environmental condition map. For example, for use cases in which the consumer is an operator or other personnel associated with the industrial process plant, the method 400 may include, at a block 410, causing the environmental condition map to be presented on a display view at a user interface associated with the industrial process plant, such as an operator interface 150a, 150c,105d, and/or at a remote user interface 150b. The user interface may be associated with the lighting network, the process control system, or both the lighting network and the process control system, for example. In such embodiments, the environmental condition map may be presented 410 at the user interface in a graphical format. For example, indications of respective conditions which have been sensed or detected may be displayed on a graphical representation of the physical layout of the process plant. The indications may be displayed using any suitable format such as, for example, red/yellow/green, alphanumeric or graphical representations of measurements, time-based graphs, etc. In some implementations, the displayed environmental condition map may be continually updated over time (e.g., as updated environmental data is obtained 402 from the luminaires). For example, the environmental condition map may be presented via one or more display views which may be updated in real-time as environmental conditions change.

Further, the presented environmental condition map may be interactive, so that, for example, the operator or user may click on an indication of a detected environmental condition to obtain more details, a history, etc.; so that an operator may select among different environmental condition maps corresponding to different aspects of environmental conditions (e.g., area of the plant, type of environmental condition, particular location such as near the ceiling, down near the ground, near combustible materials, etc., and/or other aspects); so that an operator may select or filter environmental condition data for display (e.g., by condition type(s), by time interval, by rate of change, by severity, etc.); to name a few. As such, the presented environmental condition map(s) may provide the operator with a current or present view and a view over time of how various environmental conditions are unfolding or developing, so that the operator may monitor the situation and take any necessary mitigating actions.

Accordingly, in embodiments, the method 400 may include (not shown) configuring the environmental condition map display view(s) to include desired interactive elements, thresholds and/or levels of various environmental conditions which correspond to various levels of severity and/or rates of change, graphical and/or alphanumeric depictions thereof, etc. For example, the PCS servers 140 and/or the lighting network servers 138 may include a respective configuration application via which a configuration engineer may configure one or more display views on which environmental condition maps may be displayed.

Returning now to block 408, for use cases in which the consumer of the environmental condition map is the process control system, generating the environmental condition map including the indications of the detected or sensed environmental conditions at respective times/dates and respective physical locations of the physical luminaires at the industrial process plant may be generated in a data file format, and the method 400 may further include providing 412 at least a portion of the environmental condition map data file to the process control system or PCS servers 140 for ingestion, e.g., via the data highway 122. The process control system may ingest the environmental condition map data file as a source data input, and may utilize the data points of the environmental condition map data file in conjunction with other data sources to perform various process control system actions, generate process control system views, and the like. For example, the process control system may include alerts and/or alarms (and corresponding display views) which have been configured to trigger or otherwise respond to one or more detected or sensed environmental conditions, and/or their respective locations, measurements, rates of change over time, directions of change over time, occurrences of different combinations of environmental conditions, etc., and the triggering of such alerts and/or alarms may result in corresponding process control system actions, e.g., displaying the triggered alert/alarm on an operator display view, initiating a diagnostic, causing a trip or other safety action to occur, etc. In another example, various control modules executing in the process control system may ingest environmental condition data and responsively adjust their respective control routines. In still another example, other applications of the process control system (e.g., historians, analytics, diagnostics, etc.) may ingest the environmental condition data and respond accordingly. For instance, an analytics application may analyze detected environmental conditions along with process control data to perform root cause analysis or to predict occurrences of undesirable effects on the process control system, and may automatically take corresponding mitigating actions. In another example, a diagnostic application may ingest data indicative of detected environmental conditions along with other inputs to measure a response of a target device to a test signal, etc. Of course, other uses of the environmental condition map data file by the process control system may be possible. Of course, the computing device 300 may provide updates to the sensed or detected environmental conditions to the process control system as the updates are sensed or detected by the luminaires. Accordingly, the process control system display views and applications may continually operate on the most recent environmental condition sensor data.

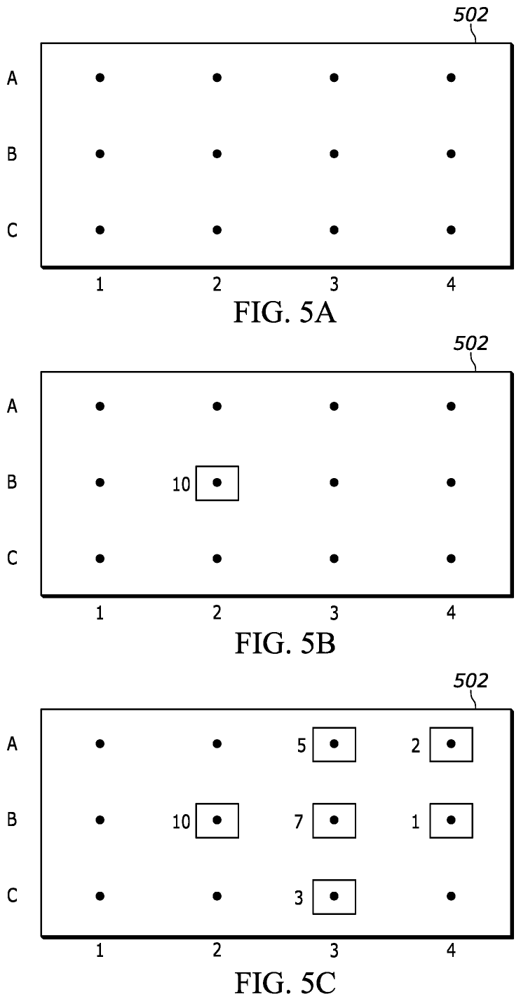

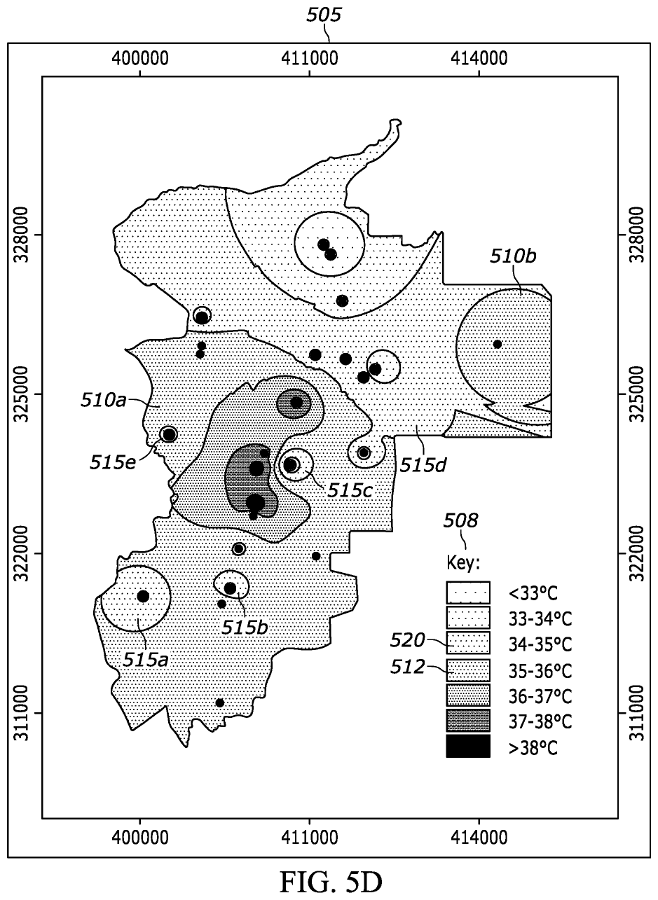

FIGS. 5A-5D illustrate various embodiments of environmental conditions maps, which may be generated by the methods, systems, and techniques disclosed herein. For example, any or all of the environmental maps illustrated in FIGS. 5A-5D may be generated by one or more of the components of the industrial environment 100 of FIG. 1, by the computing device 300 of FIG. 3, and/or by utilizing the method 400 of FIG. 4.

FIG. 5A depicts an environmental condition map 502 for a portion of the process plant including a set of luminaires, each of which includes a gas sensor. For ease of discussion, the physical locations of the luminaires are shown and labeled on FIG. 5A with coordinates A1, A4, B1 . . . B4, and C1 . . . C4. In FIG. 5A, no gas has been detected by any of the depicted luminaires, and as such, no indication of detected gas is visible on the map 502.

FIG. 5B depicts the environmental condition map 502 for the same process plant portion and luminaires as shown in FIG. 5A; however, in FIG. 5B, the gas sensor of luminaire B2 has detected a gas measurement of “10,” and none of the other luminaires has detected any gas. Accordingly, the environmental condition map 502 has been updated to indicate a gas measurement of 10 detected by the luminaire B2.

FIG. 5C depicts the environmental condition map 502 for the same process plant portion and luminaires as shown in FIGS. 5A and 5B at a time later than the time at which FIG. 5B was displayed. Here, various gas sensors have detected the gas, as indicated by the respective measurements displayed at corresponding physical locations on the updated environmental condition map. The map 502 of FIG. 5C thus illustrates that the gas is dispersing from a location near luminaire B2 towards areas of the plant denoted by the right side of the map and, moreover, the detection of the gas by luminaire B2 has not abated from its initial detection level (i.e., “10”) shown in FIG. 5B. An operator may observe the gas dispersion information depicted on the environmental condition map 502 and take any necessary mitigating actions to protect the process, equipment, and/or personnel, and in particular those who are located in areas of the process plant in which and towards which the gas is dispersing.

FIG. 5D illustrates another environmental condition map 505 of another portion of the process plant. In FIG. 5D, physical locations of luminaires are indicated by the black, circular dots. Each of the shaded areas shown on the map 505 denotes a respective isothermal range of a corresponding physical area of the process plant, (e.g., the corresponding area of spread or the dispersion of the isothermal range), where the different shades indicative of different possible isothermal ranges are defined by a key 508. For example, each of areas 510a and 510b is in the same isothermal range 512, and each of areas 515a-515e is in another isothermal range 520. The areas and the corresponding isothermal ranges may be determined based on the signals transmitted by the luminaires and indicative of sensed ambient temperature measurements. For example, a computing device, such as the computing device 300, may obtain signals from the luminaires indicative of sensed ambient temperature, and may determine the corresponding isothermal ranges of the different areas based on the ambient temperature information included in the signals as well as based on other environmental information such as facility structures, wind direction, wind speed, solar influences, etc. The additional environmental information may be obtained from luminaires on which corresponding sensors are disposed, and/or from other sensor systems.

As such, the computing device 300 may determine or calculate various types of information corresponding to an environmental condition and present indications thereof on an environmental condition map. For example, the computing device 300 may determine or calculate a relative magnitude of the environmental condition (e.g., a deviation from a desired isothermal range, not shown in FIG. 5D), a behavior over time of the environmental condition (e.g., time-based graphs or dynamically changing maps), a respective rate of change of the environmental condition at different physical locations, an area of spread or dispersion of the environmental condition (e.g., the isothermal range areas shown in FIG. 5D, the locations at which gas has been detected as shown in FIG. 5C), an amount of spread or dispersion of the environmental conditions (e.g., the measurements of gas at different physical locations as shown in FIG. 5C), and/or other types of information which may be determined or calculated by the computing device 300 based on multiple signals received over time from a luminaire, or based on multiple signals received from multiple luminaires.

The following additional considerations apply to the foregoing discussion.

A user interface device, personal electronic device, or portable computing device, such as the devices 150b, 150c, 150d, which may operate in conjunction with embodiments of methods, systems, luminaires, and computing devices disclosed herein, can be any suitable device capable of wireless communications such as a smartphone, a tablet computer, a laptop computer, a wearable or body-borne device, a drone, a camera, a media-streaming dongle or another personal media device, a wireless hotspot, a femtocell, or a broadband router. Further, the portable computing device and/or embodiments of the disclosed luminaire can operate as an internet-of-things (IoT) device or an Industrial internet-of-things (IIoT) device.

Certain embodiments are described in this disclosure as including logic or a number of components or modules. Modules may be software modules (e.g., code stored on non-transitory machine-readable medium) or hardware modules. A hardware module is a tangible, non-transitory unit capable of performing certain operations and may be configured or arranged in a certain manner. A hardware module can include dedicated circuitry or logic that is permanently configured (e.g., as a special-purpose processor, such as a field programmable gate array (FPGA) or an application-specific integrated circuit (ASIC)) to perform certain operations. A hardware module may also include programmable logic or circuitry (e.g., as encompassed within a general-purpose processor or other programmable processor) that is temporarily configured by software to perform certain operations. The decision to implement a hardware module in dedicated and permanently configured circuitry, or in temporarily configured circuitry (e.g., configured by software) may be driven by cost and time considerations.

When implemented in software, the techniques can be provided as part of the operating system, a library used by multiple applications, a particular software application, etc. The software can be executed by one or more general-purpose processors or one or more special-purpose processors.

Upon reading this disclosure, those of skill in the art will appreciate still additional alternative structural and functional designs for the embodiments of the luminaires, systems, and computing devices disclosed herein through the principles disclosed in this disclosure. Thus, while this document illustrates and describes particular embodiments and applications, the disclosed embodiments are not limited to the precise construction and components disclosed. Various modifications, changes and variations, which will be apparent to those of ordinary skill in the art, may be made in the disclosed arrangement, operation and details of the method, and apparatus without departing from the spirit and scope defined in the appended claims.

1. A method for generating a map of environmental conditions of an industrial process plant, the method comprising:
obtaining, at a computing device, a representation of a physical layout of at least a portion of the industrial process plant from a process control system or an asset management system of the industrial process plant;
obtaining, by the computing device from each luminaire of a plurality of luminaires configured and disposed to provide illumination at the industrial process plant, a respective signal indicative of an environmental condition of the industrial process plant detected by the each luminaire;
generating, by the computing device based on the representation of the physical layout of the industrial process plant, a map including indications of the detected environmental condition at respective map locations corresponding to respective physical locations of the plurality of luminaires at the industrial process plant, thereby generating a map of the environmental condition for the industrial process plant; and
causing the environmental condition map to be presented at a user interface associated with the industrial process plant.

2. The method of claim 1, wherein generating the environmental condition map includes overlaying the representation of the physical layout of the at least the portion of the industrial process plant with the indications of the detected environmental condition.

3. The method of claim 1, wherein obtaining the respective signal indicative of the environmental condition of the industrial process plant detected by the each luminaire includes obtaining the respective signal indicative of ambient temperature, humidity, ambient visible light, motion, air flow, a particular gas, sound or noise, or vibration detected by one or more corresponding sensors included in the each luminaire.

4. The method of claim 1, wherein:
the plurality of luminaires is communicatively connected via a lighting network via which lighting control messages are delivered to thereby control the illumination provided by the plurality of luminaires at the industrial process plant; and
obtaining the respective signal indicative of the detected environmental condition from the each luminaire includes obtaining the respective signal indicative of the detected environmental condition from the lighting network.

5. The method of the preceding claim 4, wherein:
process control devices of the process control system are communicatively connected via a process control network of the process control system via which process control messages are delivered therebetween to thereby control an industrial process executing in the industrial process plant;
at least a portion of the lighting network and at least a portion of the process control network are an integral wireless network managed by a network manager or gateway; and
obtaining the respective signal indicative of the detected environmental condition includes obtaining the respective signal via the integral wireless network.

6. The method of claim 1, wherein causing the environmental condition map to be presented at the user interface associated with the industrial process plant includes causing the environmental condition map to be presented at an operator interface or a remote user interface of the process control system.

7. The method of claim 6, further comprising causing the environmental condition map to be presented at a user interface of the lighting network.

8. The method of claim 1, wherein:
the process control system of the industrial process plant is configured with an alert or alarm corresponding to the environmental condition; and
the method further comprises providing, by the computing device to the process control system, a signal indicative of the detection of the environmental condition and at least one physical location at which the environmental condition was detected to thereby cause the process control system to generate the alert or the alarm.

9. The method of claim 1, wherein:
the environmental condition is a first environmental condition; and
obtaining the respective signal indicative of the first environmental condition detected by the each luminaire of the plurality of luminaires includes obtaining, from one or more luminaires of the plurality of luminaires, respective signals indicative of a plurality of environmental conditions detected by each of the one or more luminaires, the plurality of environmental conditions including the first environmental condition; and
at least one of:
indicating each detected environmental condition on the environmental condition map; or
indicating different environmental conditions on different environmental condition maps.

10. The method of claim 1, wherein:
obtaining the respective signal indicative of the environmental condition detected by the each luminaire includes obtaining a respective measurement of the environmental condition obtained by the each luminaire; and
the respective indications of the detected environmental condition included in the environmental condition map are indicative of the respective measurements.

11. The method of claim 1, further comprising:
obtaining, from at least a subset of the plurality of luminaires, a respective signal indicative of an update to the environmental condition detected by each luminaire included in the at least the subset; and
updating the environmental condition map based on the updates.

12. A system for generating a map of environmental conditions of an industrial process plant, the system comprising:
a representation of a physical layout of at least a portion of the industrial process plant, the representation of the physical layout stored in one or more tangible, non-transitory memories of the industrial process plant;
a communication interface to a lighting network, the lighting network including a plurality of luminaires physically disposed at respective physical locations of the industrial process plant and configured to provide illuminations at the industrial process plant; and
a set of computer-executable instructions stored on the one or more tangible, non-transitory memories that, when executed by one or more processors of the system, cause the system to:
obtain, via the communication interface from each luminaire of the plurality of luminaires, a respective signal indicative of one or more environmental conditions of the industrial process plant detected by the each luminaire;
based on the obtained respective signals, indicate, on the representation of the physical layout of the at least the portion of the industrial process plant at respective map locations corresponding to respective physical locations of the plurality of luminaires, respective detections of the one or more environmental conditions, thereby generating a map of the one or more environmental conditions for the industrial process plant; and
cause the environmental conditions map to be presented at one or more user interfaces associated with the industrial process plant.

13. The system of claim 12, wherein the one or more environmental conditions of the industrial process plant detected by the each luminaire includes one or more of ambient temperature, humidity, ambient visible light, motion, air flow, a particular gas, sound or noise, or vibration detected by one or more sensors included in the each luminaire.

14. The system of claim 12, wherein:
the lighting network is communicatively connected with a process control network of the industrial process plant, the process control network communicatively connecting process control devices to deliver process control messages therebetween to thereby control an industrial process executing in the industrial process plant; and
at least a portion of the lighting network and at least a portion of the process control network are an integral wireless network.

15. The system of claim 14, wherein the integral wireless network is managed by a network manager or gateway that generates a network schedule indicating respective designated times during which nodes of the integral wireless network are allowed to communicate over the integral wireless network using a time-synchronized protocol.

16. The system of claim 12, wherein the user interface associated with the industrial process plant includes one or more of: a user interface of the lighting network, an operator interface of a process control system of the industrial process plant, or a remote user interface of the process control system.

17. The system of claim 12, wherein the representation of the physical layout of the at least the portion of the industrial process plant is obtained from an asset management system of the industrial process plant.

18. The system of claim 12, wherein:
the communication interface is a first communication interface;
the system further comprises a second communication interface to a process control system of the industrial process plant, the process control system configured with an alert or alarm corresponding to the environmental condition; and
the set of computer-executable instructions are executable by the one or more processors to cause the system further to provide, to the process control system via the second communication interface, a signal indicative of the detection of the one or more environmental conditions and at least one physical location of the industrial process plant at which the one or more environmental conditions were detected to thereby cause the process control system to generate the alert or the alarm.

19. The system of claim 12, wherein:
the one or more environmental conditions is a plurality of environmental conditions; and
at least one of:
each detected environmental condition is indicated on the environmental condition map; or
different detected environmental conditions are indicated on different environmental condition maps.

20. The system of claim 12, wherein:
the respective signal indicative of the one or more environmental conditions detected by the each luminaire includes respective measurements of the one or more environmental conditions obtained by the each luminaire; and
the respective measurements of the detected one or more environmental conditions are indicated on the environmental condition map.
